(19) United States
(12) Patent Application Publication
(10) Pub. No.: US 2024/0200530 A1
(43) Pub. Date: Jun. 20, 2024

(54) ROTOR BLADE OF A WIND TURBINE, WIND TURBINE AND ASSOCIATED METHOD

(71) Applicant: Wobben Properties GmbH, Aurich (DE)

(72) Inventors: Dimitrios Bekiropoulos, Aurich (DE); Christoph Scheit, Aurich (DE); Jochen Stemberg, Aurich (DE)

(21) Appl. No.: 18/544,040

(22) Filed: Dec. 18, 2023

(30) Foreign Application Priority Data
Dec. 19, 2022 (EP) 22214731.6

(51) Int. Cl. F03D 1/06

(52) U.S. Cl. CPC F03D 1/069; F05B 2230/23; F05B 2230/60; F05B 2240/301; F05B 2240/3042; F05B 2250/12; F05B 2260/96

(57) ABSTRACT

Some embodiments relate to a rotor blade of a wind turbine, a wind turbine having a rotor blade and a method for optimizing a rotor blade. Some embodiments relate to a rotor blade of a wind turbine, wherein the rotor blade has a leading edge, a trailing edge, a suction side and a pressure side, and extends in a longitudinal direction of a rotor blade between a root end and a tip end, wherein a direct connection between the leading edge and the trailing edge is termed the chord line and the length thereof is termed the chord length, wherein the rotor blade has at least one airfoil element, wherein the at least one airfoil element is arranged at the trailing edge with a proximal portion adjoining a trailing edge region and projects from the trailing edge with a distal portion having a projecting direction, which is oriented substantially parallel to the direction of the chord length, wherein the at least one airfoil element has an airfoil element thickness in a direction perpendicular to the projecting direction, wherein the at least one airfoil element has a pressure side airfoil side facing the pressure side and a suction side airfoil side facing the suction side, wherein the at least one airfoil element has a cross-section substantially orthogonal to the projecting direction, characterized in that the cross-section of the at least one airfoil element has at least one local minimum of the airfoil element thickness, wherein the airfoil element thickness in the cross-section on both sides of the local minimum has a larger value.

### BACKGROUND

### Technical Field

Embodiments of the invention relate to a rotor blade of a wind turbine, a wind turbine having a rotor blade and a method for optimizing a rotor blade.

### Description of the Related Art

Wind turbines are known; they generate electrical power from wind. Wind turbines usually relate to so-called horizontal-axis wind turbines, wherein the rotor axis is arranged substantially horizontally and the rotor blades sweep over a substantially perpendicular rotor area. In addition to a rotor arranged at a nacelle, wind turbines usually comprise a tower where the nacelle with the rotor is arranged rotatably around a substantially vertically oriented axis. The rotor usually comprises one, two or more rotor blades of equal length. The rotor blades are thin elements, which are often made of fiber-reinforced plastic.

The shaping of the outer contour of the rotor blades is typically defined by arranging different airfoil sections adjacent to one another in a row. A rotor blade usually comprises a plurality of different airfoil sections. The airfoil sections are intended to enable a substantially aerodynamically ideal flow course at the various radial positions of a rotor blade. In spite of continuous aerodynamic improvements on rotor blades, it can be observed that a plurality of wind turbines emit noise to be noticed by people. The noise emitted by wind turbines is caused, among other things, by aerodynamic effects at the trailing edges of the rotor blades. This type of noise emission, which is also known as trailing edge noise, poses a limitation for aerodynamic use. To reduce noise emission the speed of a wind turbine may be reduced. Among other things, this means that in order to reduce noise emission the performance of the turbine is reduced. This results in a lower efficiency of the wind turbine.

To reduce trailing edge noise the use of so-called “trailing edge serrations” or “finlets” has been known. Trailing edge serrations are serrated airfoil elements to be arranged at the trailing edges of rotor blades. Finlets, on the other hand, are small-sized fins to be attached to the trailing edges, oriented vertically with respect to the rotor blade surface, for reducing pressure shifts over the rotor's span. The existing devices and methods for reducing trailing edge noise offer various benefits, but further improvements are desirable.

### BRIEF SUMMARY

In view of this prior art, some embodiments allow a reduction of the trailing edge noise of rotor blades.

Some embodiments include a rotor blade of a wind turbine, wherein the rotor blade has a leading edge, a trailing edge, a suction side and a pressure side, and extends in a longitudinal direction of a rotor blade between a root end and a tip end, wherein a direct connection between the leading edge and the trailing edge is termed the chord line and the length thereof is termed the chord length, wherein the rotor blade has at least one airfoil element, wherein the at least one airfoil element is arranged at the trailing edge with a proximal portion adjoining a trailing edge region and projects from the trailing edge with a distal portion having a projecting direction, which is oriented substantially parallel to the direction of the chord length, wherein the at least one airfoil element has an airfoil element thickness in a direction perpendicular to the projecting direction, wherein the at least one airfoil element has a pressure side airfoil side facing the pressure side and a suction side airfoil side facing the suction side, wherein the at least one airfoil element has a cross-section substantially orthogonal to the projecting direction, characterized in that the cross-section of the at least one airfoil element has at least one local minimum of the airfoil element thickness, wherein the airfoil element thickness in the cross-section on both sides of the local minimum has a larger value.

The rotor blade extends in the directions of the rotor blade length, the chord length and the airfoil thickness. In the direction of the rotor blade length, the rotor blade preferably extends between a rotor blade root and a rotor blade tip. The chord length is oriented, in particular, orthogonally to the rotor blade length. During operation, the rotor blade depth is oriented substantially parallel to the inflow direction of the rotor blade. The rotor blade extends in the direction of the airfoil thickness orthogonally to the direction of the rotor blade length and the chord length. At substantially each position along the rotor blade length, the chord length and the airfoil thickness span an aerodynamic airfoil, which may also be understood as an airfoil section.

The rotor blade comprises at least one airfoil element. The at least one airfoil element has the proximal portion and the distal portion. The proximal portion of the at least one airfoil element is particularly characterized in that it does not project from the trailing edge, but is arranged at the trailing edge region. The distal portion of the at least one airfoil element is characterized in that it projects from the trailing edge in the projecting direction.

The trailing edge region preferably comprises a region which extends up to a distance of 20% of the local chord line, preferably up to a distance of 5% of the local chord line, particularly preferred up to a distance of 1% of the local chord line, starting from the trailing edge. In this way, the trailing edge region extends onto the pressure side and onto the suction side of the rotor blade.

The projecting direction of the at least one airfoil element at a given position along the rotor blade length is given, for this position, by the connection from the point where the chord line intersects the trailing edge to the point of the airfoil element that is furthest away from the trailing edge in this position, wherein only the part of the at least one airfoil element located behind the trailing edge in the direction of the chord line is considered here, i.e., the distal portion.

The projecting direction is oriented substantially parallel to the direction of the chord length. In particular, “substantially parallel to the direction of the chord length” means that an angle of preferably less than 30°, less than 15°, less than 10° or particularly preferred less than 5° is formed between the projecting direction and the direction of the chord length.

The airfoil element thickness extends in a direction perpendicular to the projecting direction between a plane spanned by the trailing edge and the projecting direction and the surface of the at least one airfoil element. The airfoil element thickness is to be understood as a positive quantity in both possible directions.

A local minimum of the airfoil element thickness of the cross-section of the at least one airfoil element is to be understood as a point of the cross-section having an airfoil element thickness in a perpendicular direction to the projecting direction smaller than the airfoil element thickness on both sides of the local minimum. “On both sides of the local minimum” refers to the two points directly adjacent to the local minimum in cross-section, wherein the points having the same airfoil element thickness as the local minimum are not considered, and in this case the closest point having an airfoil element thickness not equal to the local minimum is considered.

Some embodiments are based on the finding that a rotor blade having the at least one airfoil element, wherein the cross-section of the at least one airfoil element has at least one local minimum of the airfoil element thickness, exhibits improved noise emission. The inventors found that the at least one airfoil element improves the outflow pattern of the rotor blade. The at least one airfoil element described above disrupts the turbulent structures in the boundary layer. Moreover, the at least one airfoil element changes the directivity pattern of the dominant noise sources in such a way that the emissions of the noise source become more diffuse and, ideally, less noise reaches the prescribed measuring position for noise level measurements of the wind turbine. Up to now, a maximum value of the noise level caused by the dipole-like emission pattern of the trailing edge noise tends to occur at this measuring position.

The at least one airfoil element described above may be arranged on a rotor blade, even a rotor blade already attached to a rotor, with little effort. Thus, the at least one airfoil element described above is also useful as a retrofit solution for existing turbines.

According to a preferred embodiment of the rotor blade, the at least one airfoil element has multiple cross-sections at different positions in a direction parallel to the projecting direction, wherein each of the multiple cross-sections has at least one respective local minimum of the airfoil element thickness on a common line, wherein the connection of all local minimums on a common line is termed a groove, and wherein each of the multiple cross-sections has at least one respective local maximum of the airfoil element thickness on a common line, wherein the connection of all local maximums on a common line is termed a ridge line.

When all of the multiple cross-sections, or only some of the cross-sections, have one or more respective local minimums of the airfoil element thickness, it will be understood that one or more respective local minimums may be on different grooves. For example, when all or multiple cross-sections each have two local minimums of the airfoil element thickness, they may be on one, two or more grooves when the respective local minimums are not present along the entire at least one airfoil element in the projecting direction. For example, when all or multiple cross-sections each have two local minimums of the airfoil element thickness and the respective local minimums are present along the entire at least one airfoil element in the projecting direction, the respective two local minimums of the airfoil element thickness of the all or multiple cross-sections are on two grooves.

When all of the multiple cross-sections, or only some of the cross-sections, have one or more respective local maximums of the airfoil element thickness, it will be understood that one or more respective local maximums may be on different ridge lines. For example, when all or multiple cross-sections each have two local maximums of the airfoil element thickness, they may be on one, two or more ridge lines when the respective local maximums are not present along the entire at least one airfoil element in the projecting direction. For example, when all or multiple cross-sections each have two local maximums of the airfoil element thickness and the respective local minimums are present along the entire at least one airfoil element in the projecting direction, the respective two local maximums of the airfoil element thickness of the all or multiple cross-sections are on two ridge lines.

The surface of the at least one airfoil element may disclose a rounded or an edge shape on a ridge line and/or a groove.

According to an advantageous embodiment of the rotor blade, the at least one airfoil element has an airfoil surface for each groove, located on the rotor blade root side of the individual grooves and extending between the respective groove and the ridge line, which is located on the same airfoil side directly on the rotor blade root side of the individual groove, wherein the airfoil surface has an airfoil element thickness decreasing in the direction of the rotor blade tip side, and an airfoil surface located on the rotor blade tip side of the individual grooves and extending between the respective groove and the ridge line, which is located on the same airfoil side directly on the rotor blade tip side of the individual groove, wherein the airfoil surface has an airfoil element thickness increasing in the direction of the rotor blade tip side, wherein each airfoil surface is formed convex, concave or straight.

The description of the airfoil surface as being convex, concave or straight is to be understood in a macroscopic sense. This means that an airfoil surface in convex, concave or straight form and only deviating therefrom in small portions is to be understood as a convex, concave or straight airfoil surface.

For example, an airfoil surface which is formed corrugated, but still discloses an overall concave form, is understood as a concave chord line. A straight surface means that the entire surface is flat.

A groove does not have to be present over the entire length of the airfoil element in the projecting direction; it may extend, for example, over 50% or any other percentage of the length of the airfoil element.

According to a further preferred embodiment, the at least one airfoil element has a first airfoil surface on the pressure side airfoil side and/or on the suction side airfoil side, starting from a rotor blade root side, wherein the first airfoil surface has an airfoil element thickness increasing in the direction of the rotor blade tip side, and wherein the first airfoil surface reaches its maximum airfoil element thickness along a first ridge line, which extends parallel to the chord line, wherein each airfoil surface is formed convex, concave or straight.

According to a preferred embodiment of the rotor blade, the at least one airfoil element has a final airfoil surface on the pressure side airfoil side and/or on the suction side airfoil side, starting from a rotor blade root side, on the rotor blade tip side of the final ridge line, in the direction of the rotor blade tip side, wherein the final airfoil surface has an airfoil element thickness decreasing in the direction of the rotor blade tip side, and wherein the final airfoil surface reaches its minimum airfoil element thickness along the edge of the at least one airfoil element, wherein each airfoil surface is formed convex, concave or straight.

According to a particularly preferred embodiment of the rotor blade, each airfoil surface of the at least one airfoil element extends from a distal end towards a proximal end of the at least one airfoil element.

According to a preferred embodiment of the rotor blade, each airfoil surface of the at least one airfoil element adjoining a groove is formed substantially congruent with the second airfoil surface adjoining the same groove.

A surface is congruent with a second surface when the second surface may be obtained from the first surface via parallel translation, rotation, reflection or a combination of these operations.

According to a preferred embodiment of the rotor blade, at least one ridge line of the at least one airfoil element has a sharp edge.

A sharp edge is present when the minimum diameter of a circle, which contacts both surfaces forming the edge on the same height as the center of the circle for various given heights of the center of the circle, and preferably is two times smaller than the distance from the center of the circle to the edge, particularly preferred is five times smaller than the distance from the center of the circle to the edge and most preferred is ten times smaller than the distance from the center of the circle to the edge. Preferably, this condition has to be met for the final 2%, particularly preferred for the final 10%, most preferred for the final 30% of the height of the edge, wherein this height is measured perpendicularly to the projecting direction from the rotor blade surface to the edge.

A sharp edge has the benefit that it deflects air flows which are not parallel to this sharp edge.

According to a preferred embodiment of the rotor blade, at least one groove of the at least one airfoil element has a sharp edge.

The definition of the sharp edge for the ridge line also applies to the groove according to this embodiment in an analogous manner.

According to a preferred embodiment of the rotor blade, each ridge line and each groove of the pressure side airfoil side of the at least one airfoil element is arranged perpendicularly with respect to the projecting direction in each point, below the respective ridge line or the respective groove of the suction side airfoil side of the at least one airfoil element.

According to a preferred embodiment of the rotor blade, the pressure side airfoil side of the at least one airfoil element is a reflection of the corresponding suction side airfoil side with respect to the plane spanned by the trailing edge and the projecting direction.

According to a preferred embodiment of the rotor blade, the proximal portion and the distal portion of the at least one airfoil element are formed in the shape of arrowheads, wherein the proximal end and the distal end each are formed substantially round or pointed; for example, the proximal end may be pointed and the distal end may be round.

It should be noted here that the airfoil element may also have multiple arrowhead-shaped ends adjacent to one another in the longitudinal direction of the rotor blade.

For example, when the distal end is round and the proximal end is pointed, this results in a drop shape for the airfoil element, with the airfoil element considered as a whole herein. As long as one of the ends, herein it is the proximal end, is pointed, a drop shape is also understood as being arrowhead-shaped as described herein.

According to a preferred embodiment of the rotor blade, the proximal portion and the distal portion of the at least one airfoil element are composed of multiple arrowhead shapes arranged parallel to one another. Each of the arrowhead shapes adjoins the directly adjacent arrowhead shape; in particular the respective airfoils overlap one another. This means that the respective adjacent arrowhead shapes may have a contour that appears laterally cut when compared to isolated arrowhead shapes. For the shape of the respective proximal and distal ends the lateral cutting is irrelevant, however.

An arrowhead shape means any shape which may be used as the head of an arrow. In particular, an arrowhead shape is obtained when the airfoil element terminates in a needle-pointed shape at this position or these adjacent positions, wherein the cross-section of the arrowhead is not limited and may be formed round, triangular, quadrangular, octagonal or in any other shape.

Preferably, the multiple arrowhead shapes arranged parallel to one another have grooves as described herein at the respective positions where the adjacent arrowhead shapes overlap or are arranged contacting one another.

In both cases, for the round and the pointed ends, the surfaces forming the round or pointed ends are convex, concave or straight. Preferably, each end is formed by two surfaces, which are separated by a ridge line, in particular perpendicular to the projecting direction, wherein the individual surfaces are concave, convex or straight.

The two surfaces are formed on both the suction side and the pressure side and define the contour of the airfoil element, in particular the airfoil element thickness.

According to a preferred embodiment of the rotor blade, a mounting gap is formed between the pressure side airfoil side and the suction side airfoil side in the proximal portion, wherein the trailing edge region is at least partially, preferably entirely, arranged inside the mounting gap.

Preferably, the mounting gap is formed such that the at least one airfoil element may be pushed onto the trailing edge region of the rotor blade via the mounting gap. Preferably, the airfoil element may be glued in this position. Preferably, there is a plane within the mounting gap, acting as a reflection plane for the pressure side airfoil side and the suction side airfoil side.

According to a preferred embodiment of the rotor blade, the at least one airfoil element is formed as two parts, wherein a first part has the pressure side airfoil side and a second part has the suction side airfoil side, wherein the first part is attached to the pressure side and the second part is attached to the suction side, preferably by gluing, wherein preferably the portions of the first part and the second part projecting from the trailing edge are attached together, preferably glued.

A two-part form of the at least one airfoil element simplifies the production of the at least one airfoil element by reducing its complexity.

According to a preferred embodiment of the rotor blade, the element thickness forms between the pressure side airfoil side and the suction side airfoil side of the at least one airfoil element, wherein the element thickness increases from the proximal end towards a maximum element thickness at an airfoil element position and the element thickness decreases from this airfoil element position towards the distal end.

According to a preferred embodiment of the rotor blade, the rotor blade comprises two or more airfoil elements that are arranged adjacent to one another along the trailing edges and abut against one another.

In some embodiments, a wind turbine is disclosed, comprising at least one rotor blade as described herein or a preferred design of the rotor blade.

The wind turbine may comprise any number of rotor blades greater than or equal to one, wherein at least one of the rotor blades comprises the rotor blade according to the disclosure or a preferred design of the rotor blade.

In some embodiments, a wind farm is disclosed, comprising multiple wind turbines, wherein at least one of these wind turbines is formed as described herein.

In some embodiments, a method for optimizing a rotor blade is disclosed, wherein the rotor blade has a leading edge, a trailing edge, a suction side and a pressure side, and extends in a longitudinal direction of a rotor blade between a root end and a tip end, wherein a direct connection between the leading edge and the trailing edge is termed the chord line and the length thereof is termed the chord length, comprising: assembling at least one airfoil element, wherein the at least one airfoil element is arranged at the trailing edge with a proximal portion adjoining a trailing edge region and projects from the trailing edge with a distal portion having a projecting direction, which is oriented substantially parallel to the direction of the chord length, wherein the at least one airfoil element has an airfoil element thickness in a direction perpendicular to the projecting direction between a plane spanned by the trailing edge and the projecting direction and the surface of the at least one airfoil element, wherein the at least one airfoil element has a pressure side airfoil side facing the pressure side and a suction side airfoil side facing the suction side, wherein the at least one airfoil element has a cross-section substantially orthogonal to the projecting direction, wherein the cross-section of the at least one airfoil element has at least one local minimum of the airfoil element thickness, wherein the airfoil element thickness in the cross-section on both sides of the local minimum has a larger value.

The point in time when the step of assembling the at least one airfoil element takes place is irrelevant. The step of assembling the at least one airfoil element may be performed before commissioning the rotor blade as well as after commissioning the rotor blade.

### BRIEF DESCRIPTION OF THE SEVERAL VIEWS OF THE DRAWINGS

Further benefits and specific designs will be described with reference to the attached FIGS. below, wherein:

FIG. 1 shows a schematic, three-dimensional view of an exemplary embodiment of a wind turbine;

FIGS. 2-4 show schematic, three-dimensional detail views of a rotor blade;

FIG. 5 shows a schematic, three-dimensional view of an airfoil element;

FIG. 6 shows a schematic, two-dimensional cross-sectional view of the airfoil element shown in FIG. 5;

FIG. 7 shows a schematic, two-dimensional cross-sectional view of an airfoil element;

FIG. 8 shows a schematic, two-dimensional plan view of the airfoil element shown in FIG. 5;

FIG. 9 shows a schematic, two-dimensional side view of the airfoil element shown in FIG. 5;

FIGS. 10-16 show schematic, two-dimensional plan views of alternative embodiments of the airfoil element shown in FIG. 5;

FIGS. 17-22 show schematic, two-dimensional side views of alternative embodiments of the airfoil element shown in FIG. 5;

FIG. 23 shows a schematic, three-dimensional view of the airfoil element disclosing arrowhead shapes arranged adjacent to one another;

FIG. 24 shows a further schematic view of the airfoil element disclosing arrowhead shapes arranged adjacent to one another, wherein each arrowhead shape discloses multiple grooves and ridge lines;

FIG. 25 shows a schematic method.

In the FIGS., like elements or elements having substantially the same or similar functions are designated by like reference signs.

### DETAILED DESCRIPTION

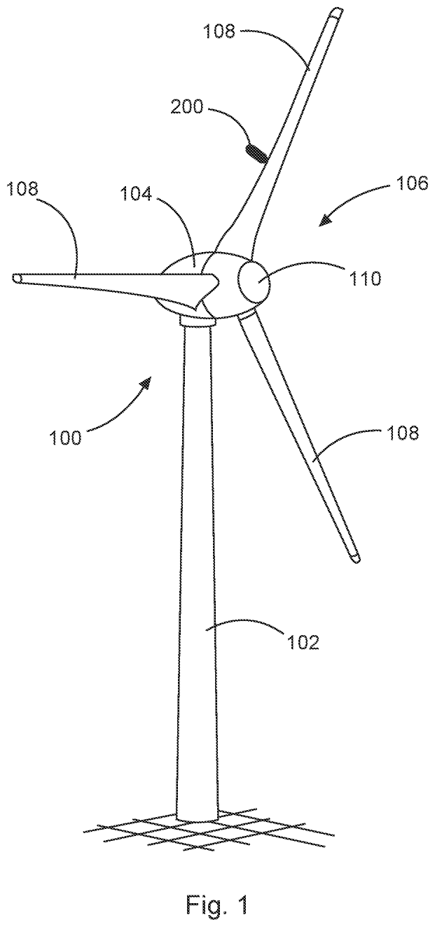

FIG. 1 shows a schematic, three-dimensional view of a wind turbine 100. The wind turbine 100 has a tower 102 and a nacelle 104 on the tower 102. An aerodynamic rotor 106 having three rotor blades 108 and a spinner 110 is provided at the nacelle 104. During operation of the wind turbine 100, the aerodynamic rotor 106 is rotated by the wind and thus also rotates an electrodynamic rotor or impeller of a generator, which is directly or indirectly coupled to the aerodynamic rotor 106. The electric generator is arranged inside the nacelle 104 and generates electrical energy.

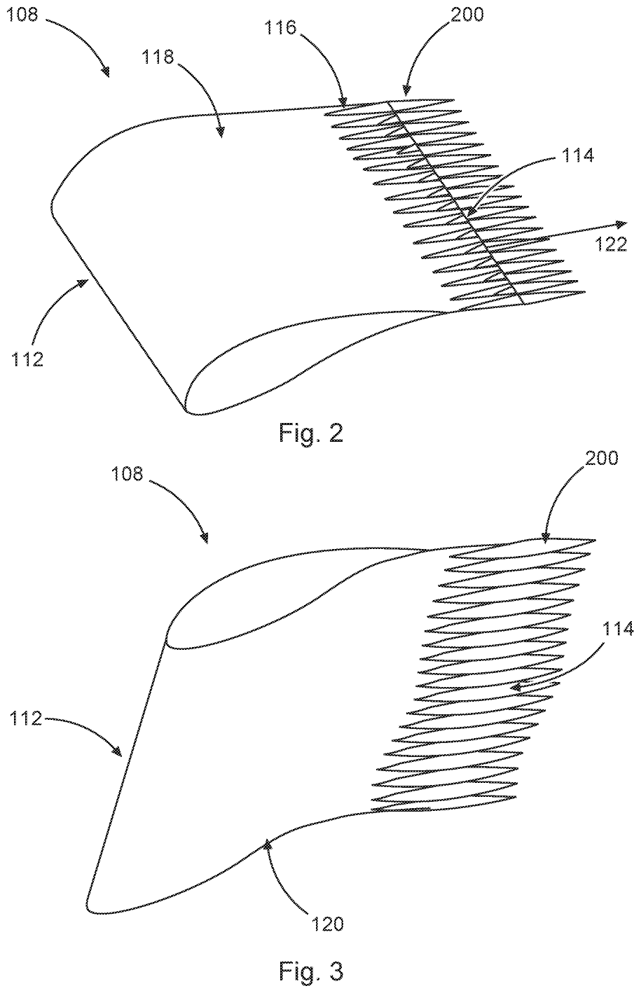

At least one airfoil element 200 is arranged on at least one of the rotor blades 108. The at least one airfoil element 200 is arranged at the trailing edge 114 of the rotor blade 108 with a proximal portion 214 adjoining a trailing edge region 116 and projects from the trailing edge 114 with a distal portion 216 having a projecting direction 122, as can be seen in FIG. 2 and FIG. 5, for example. The at least one airfoil element 200 has a cross-section substantially orthogonal to the projecting direction 122, wherein the cross-section of the at least one airfoil element 200 has at least one local minimum of the airfoil element thickness, wherein the airfoil element thickness in the cross-section on both sides of the local minimum has a larger value, as will be shown more clearly with reference to the further FIGS. below.

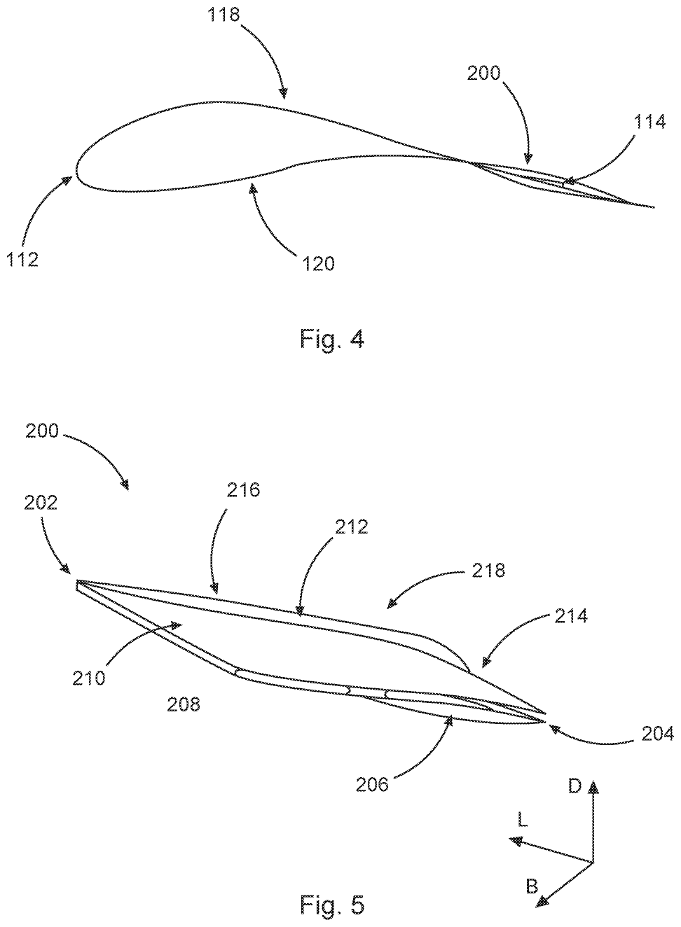

FIGS. 2 to 4 show schematic, three-dimensional detail views of a rotor blade. An airfoil thickness is formed between the suction side 118 and the pressure side 120 shown in FIGS. 3 and 4. FIG. 2 shows a portion of the rotor blade 108 viewed towards the suction side 118 of the rotor blade 108 in an angle. FIG. 3 shows a portion of the rotor blade viewed towards the pressure side 120 of the rotor blade 108 in an angle. FIG. 4 shows a cross-section of the rotor blade 108, orthogonal to the length of the rotor blade 108.

FIG. 5 shows a schematic, three-dimensional view of an arrowhead-shaped part of the at least one airfoil element 200. That is, it only shows a section of the at least one airfoil element 200, wherein preferably multiple such arrowhead-shaped parts are arranged adjacent to one another in the airfoil element 200, as shown in FIG. 2. The multiple arrowhead-shaped elements are arranged adjacent to one another in a width direction B or a longitudinal direction of the rotor blades. Similar attachments to trailing edges are also known as trailing edge serrations (TES). A preferred shape of the arrowhead shape is the drop shape, wherein the proximal or the distal end 202 or 204, respectively, does not terminate in a pointed shape, but in a round shape.

The at least one airfoil element 200 extends from a distal end 202 towards a proximal end 204. The at least one airfoil element 200 has a proximal portion 214 and a distal portion 216. During intended use of the at least one airfoil element 200, the proximal portion 214 is arranged adjacent to the rotor blade in the direction of the airfoil thickness, designated as a thickness D in the coordinate system shown in FIG. 5.

During intended use of the at least one airfoil element 200, the distal portion 216 projects from the trailing edge 114, that is, in the longitudinal direction L or chord length direction. The at least one airfoil element 200 has a mounting gap 206 in the proximal portion 214. The mounting gap 206 is arranged and formed to arrange a portion of the trailing edge region 116 therein. The mounting gap 206 makes it possible to attach the airfoil element 200 to the trailing edge 114.

Furthermore, the at least one airfoil element 200 has a ridge line 208. Preferably, the ridge line 208 is arranged in the center between the side edges of the at least one airfoil element 200. Furthermore, the at least one airfoil element 200 has a first airfoil surface 210 and a second airfoil surface 212. FIG. 5 shows the suction side airfoil side 218 in particular. The suction side airfoil side 218 has the first airfoil surface 210 and the second airfoil surface 212, wherein each is formed concave, convex or straight. The first airfoil surface 210 and/or the second airfoil surface 212 may also be formed concave, convex or straight in portions, for example by providing a transition from concave to convex without a local minimum or maximum at the position of the transition. The ridge line 208 separates the first airfoil surface 210 and the second airfoil surface 212. Analogously, the airfoil element 200 has two airfoil surfaces and a ridge line on the pressure side.

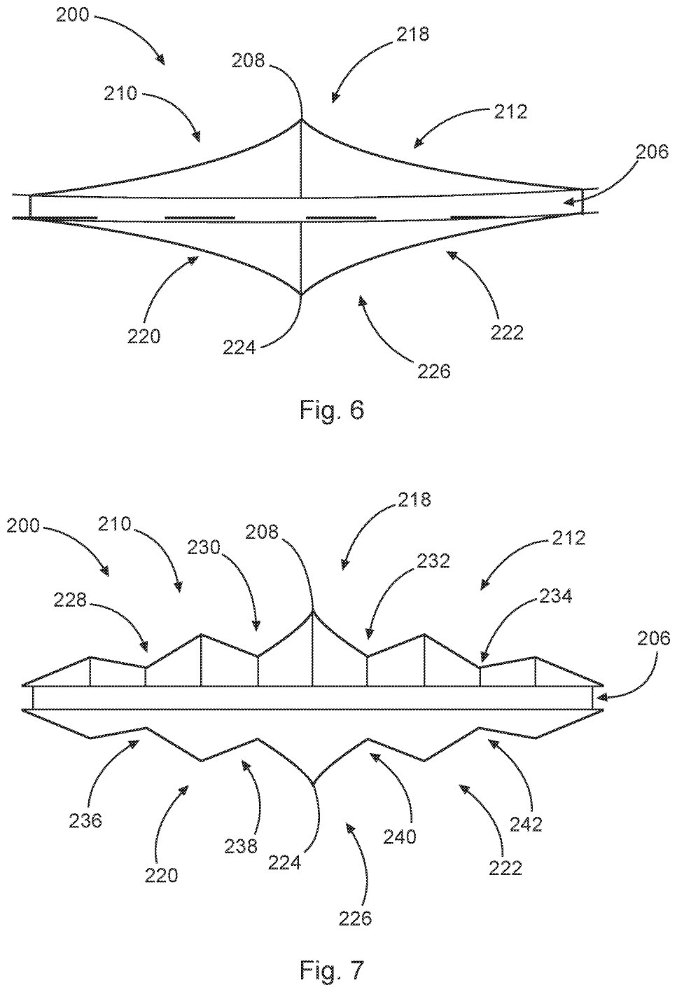

FIG. 6 shows a schematic, three-dimensional view of an arrowhead-shaped part of the at least one airfoil element 200. That is, it only shows a section of the at least one airfoil element 200. The at least one airfoil element 200 is shown in a view along the projecting direction 122 such as to provide a prominent view of the mounting gap 206. The suction side airfoil side 218 has the first airfoil surface 210 and the second airfoil surface 212, wherein both airfoil surfaces have a concave form such that they are cambered towards the inside. The pressure side airfoil side 226 has the first airfoil surface 220 and the second airfoil surface 222, wherein both airfoil surfaces have a concave form such that they are cambered towards the inside. The mounting gap 206 can be seen horizontally along the at least one airfoil element 200, wherein the mounting gap 206 is arranged and formed to arrange a portion of the trailing edge region 116 inside the mounting gap 206. FIG. 6 shows an airfoil element 200 which is symmetrical between the pressure side and the suction side, which symmetry is not required in all cases, and non-symmetrical forms are conceivable as well.

FIG. 7 shows a schematic, three-dimensional view of an airfoil element 200 in a view along the projecting direction 122, similar to FIG. 6. The airfoil surfaces 210, 212, 220, 222 on both the pressure side and the suction side are angled such that four grooves 228, 230, 232, 234 can be seen in the suction side, for example, which grooves are formed with sharp edges or, alternatively, in a rounded shape as well. The grooves 228, 230, 232, 234 correspond to a minimum in the thickness of the airfoil element 200.

The airfoil element 200 of FIG. 7 may be understood as multiple arrowhead-shaped portions arranged adjacent one another, as shown in FIG. 5, contacting or overlapping in the region of the grooves 228, 230, 232, 234. The “overlapping” results in a finite thickness of the airfoil element 200 in the region of the grooves 228, 230, 232, 234.

On the suction side airfoil side 218, five ridge lines can be seen, wherein the ridge line in the center of the view is designated by number 208. On the pressure side airfoil side 226, four grooves 236, 238, 240, 242 can be seen, which grooves are formed with sharp edges or, alternatively, in a rounded shape as well. On the pressure side airfoil side 226, five ridge lines can be seen, wherein the ridge line in the center of the view is designated by number 224. On both the suction side airfoil side 218 and the pressure side airfoil side 226, two airfoil surfaces are provided directly adjacent to each ridge line.

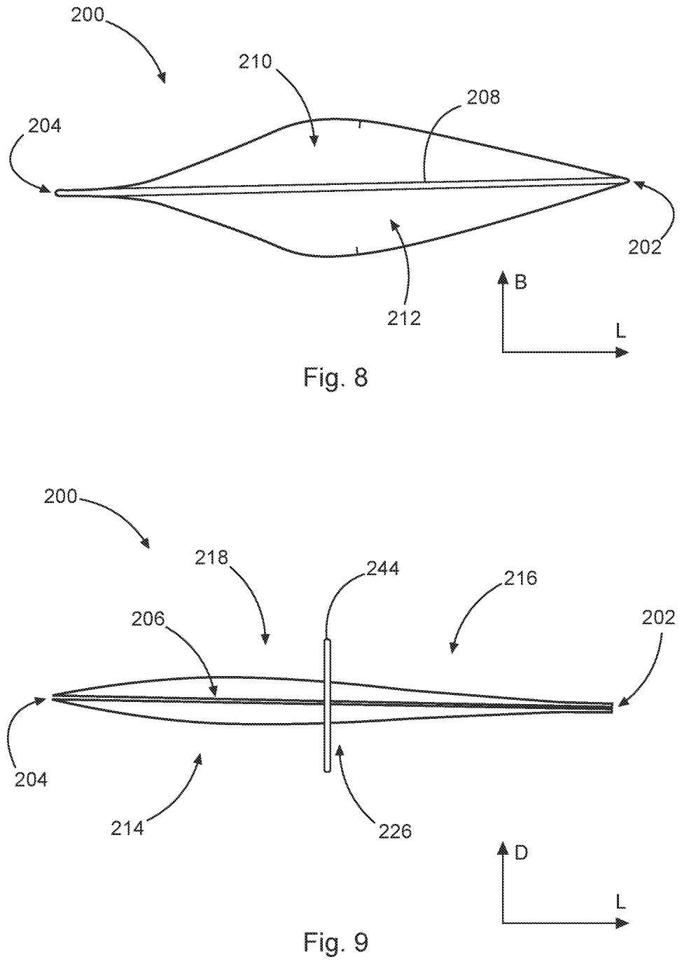

FIG. 8 shows a schematic view of a single arrowhead-shaped part of the at least one airfoil element 200. The at least one airfoil element 200 is shown in a plan view, that is, a view towards the suction side or, symmetrically, the pressure side. The coordinate system in the bottom right shows a direction of the width B of the at least one airfoil element and a direction of the length L of the at least one airfoil element 200, wherein these directions are orthogonal to one another and are in the same plane.

FIG. 8 shows a possible geometric form of the at least one airfoil element 200 in the direction of the width B and the length L of the at least one airfoil element 200. The proximal end 204 is formed in a pointed shape. Starting from the proximal end 204 towards the distal end 202, both edges, forming the edge of the at least one airfoil element 200 in the vertical direction herein, have concave shapes until substantially reaching the region in which the at least one airfoil element 200 is at its widest. Between this region and the distal end 202, both edges have convex shapes. The distal end 202 is formed in a pointed shape. Strictly speaking, the concavity already ends before reaching the widest position, as the change in curvature has to happen before. If the contour were still concave at the widest position, it would not close again. In other words, the geometry is to be understood such that the contour opens concavely and closes again convexly after a change in curvature.

A ridge line 208 is present along the entire length of the at least one airfoil element, that is, between the proximal end 204 and the distal end 202. The ridge line 208 is between the first airfoil surface 210 and the second airfoil surface 212. In FIG. 8, the extension of the outer contour of the first airfoil surface 210 and the second airfoil surface 212, in particular, can be seen. When multiple arrowhead-shaped elements are arranged adjacent to one another as an airfoil element 200, as shown in FIGS. 2, 3, 23, 24, for example, the arrowhead-shaped elements arranged adjacent to one another overlap such that parts of the individual outer contours can no longer be seen.

FIG. 9 shows a schematic view of an arrowhead-shaped part of the at least one airfoil element 200. The at least one airfoil element 200 is shown in a side view, that is, in a view in the longitudinal direction of a rotor blade. The coordinate system in the bottom right shows a direction of the length L of the at least one airfoil element 200 and a direction of the thickness D of the at least one airfoil element 200 or according to the rotor blade 108, wherein these directions are orthogonal to one another and are in the same plane. FIG. 9 shows a possible geometric form of the extension of the thickness of the airfoil element 200. Both the suction side airfoil side 218 and the pressure side airfoil side 226 are formed pointed at the proximal end 204 as well as at the distal end 202. Starting from the proximal end 204 towards the distal end 202, both edges, forming the edge of the at least one airfoil element 200 in the vertical direction herein, have convex shapes until reaching the region in which the at least one airfoil element 200 is at its thickest. Between this region and the distal end 202, both edges have convex shapes. The mounting gap 206 extends from the proximal end 204 to a projecting plane 244, wherein the projecting plane 244 defines the plane of the trailing edge of the rotor blade after which the airfoil element 200 projects towards the distal end 202.

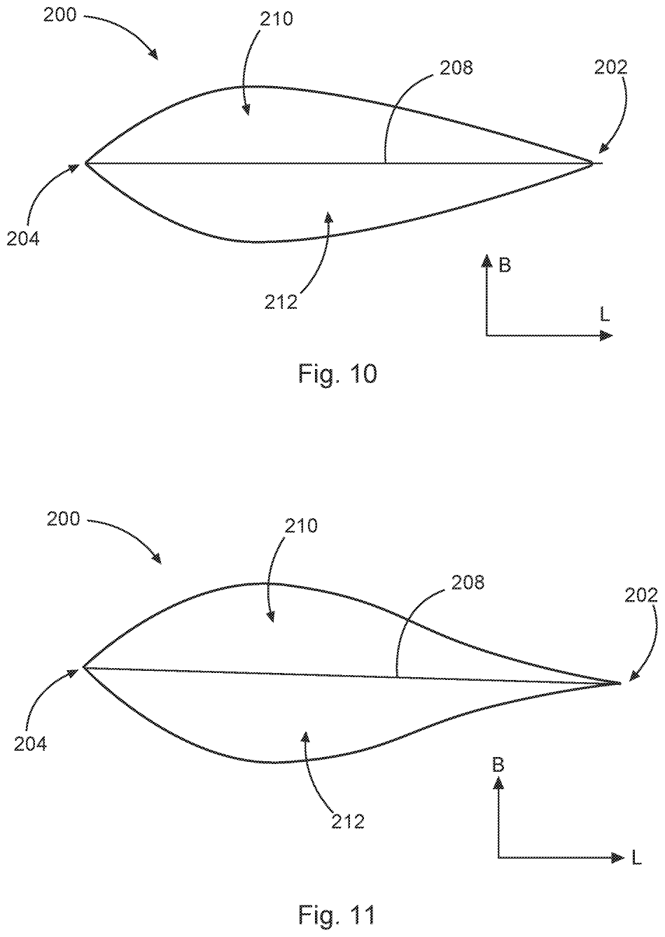

FIGS. 10 to 16 each show schematic views of arrowhead-shaped parts of airfoil elements 200. The airfoil element 200 is shown in a plan view, that is, in a view from the top. FIGS. 10 to 16 show the same view of the at least one airfoil element 200 as FIG. 8, but show alternative designs of the at least one airfoil element 200.

FIG. 10 shows a possible geometric form of the at least one airfoil element 200 in the direction of the width B and the length L of the at least one airfoil element 200. The proximal end 204 is formed in a pointed shape. Starting from the proximal end 204 towards the distal end 202, both edges, forming the edge of the at least one airfoil element 200 in the vertical direction herein, have convex shapes until reaching the region in which the at least one airfoil element 200 is at its widest. Between this region and the distal end 202, both edges have convex shapes. The distal end 202 is formed in a pointed shape.

In FIG. 11, in contrast to FIG. 10, the edges forming the outer contour have a concave shape between the widest region and the distal end 202.

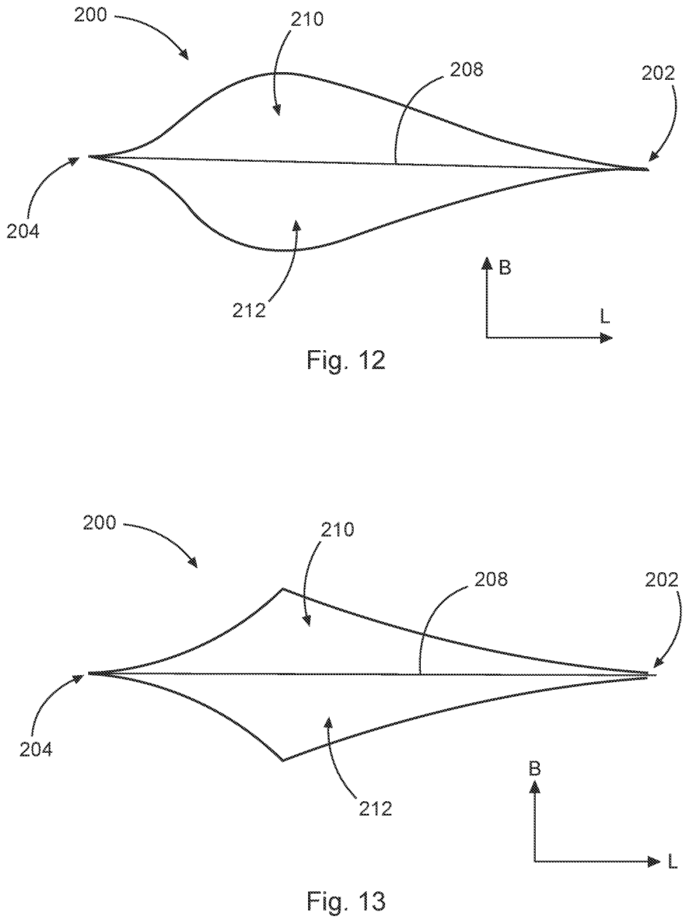

In FIG. 12 the edges forming the outer contour are formed concave on both sides of the widest region.

In FIG. 13 the outer contour is not formed rounded, but pointed, in the widest region; of course, this embodiment may be combined with any of the extensions of FIGS. 10 to 12.

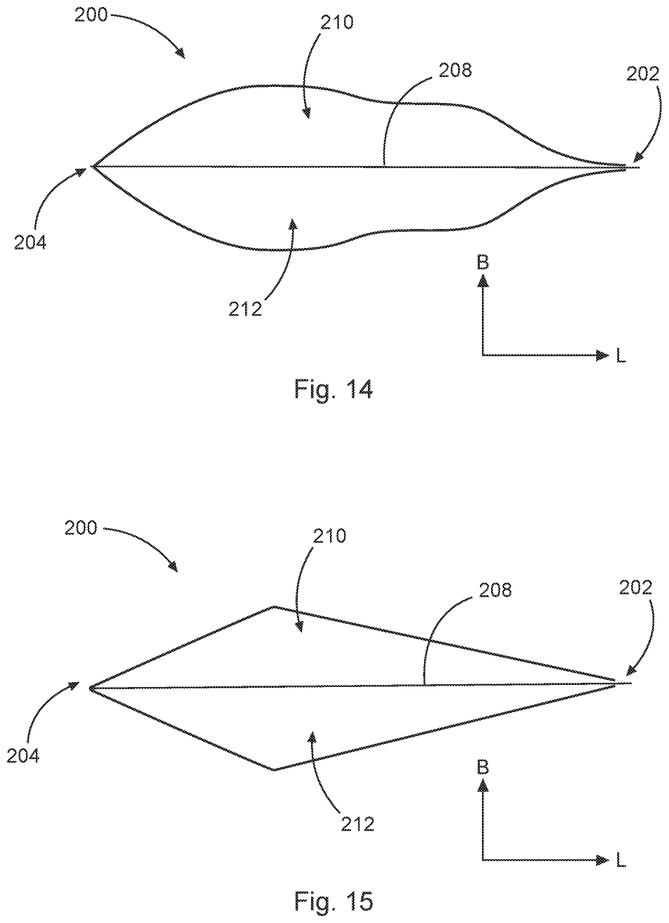

FIG. 14 shows a possible geometric form of the at least one airfoil element 200 in the direction of the width B and the length L of the at least one airfoil element 200. The proximal end 204 is formed in a pointed shape. Starting from the proximal end 204 towards the distal end 202, both edges, forming the edge of the at least one airfoil element 200 in the vertical direction herein, have convex or concave shapes in any desired number of subsequent regions. As an example, starting from the proximal end 204 towards the distal end 202, both edges, forming the edge of the at least one airfoil element 200 in the vertical direction herein, are first formed convex, then concave, again convex, and afterwards concave until reaching the distal end 202.

FIG. 15 shows a possible geometric form having straight outer contours in portions.

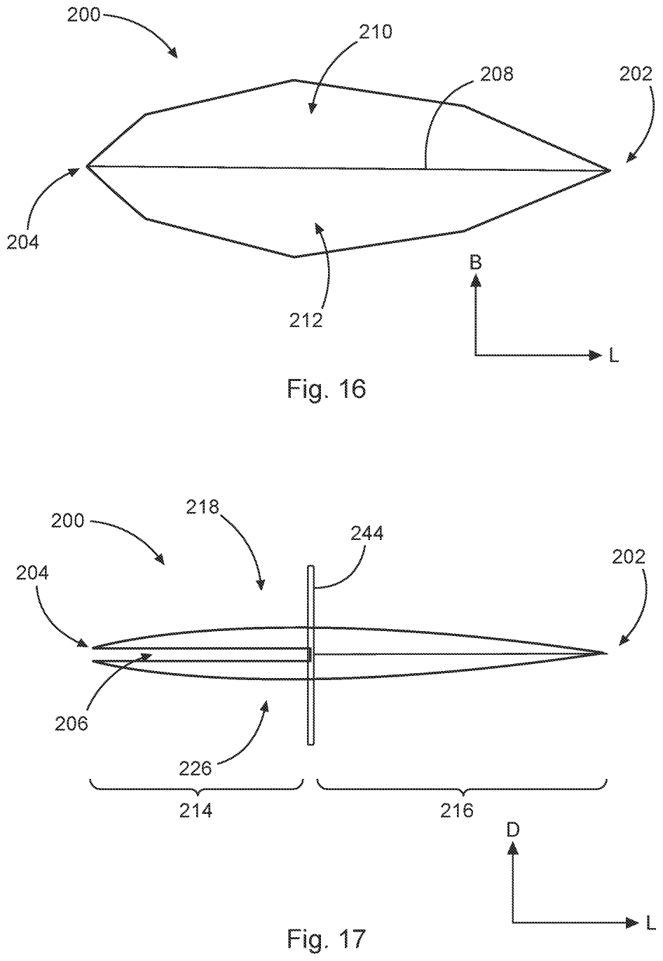

FIG. 16 shows a possible geometric form having more than two straight portions in portions of the outer contours.

FIGS. 17 to 22 each show schematic side views of arrowhead-shaped parts of airfoil elements 200 in the same view as the at least one airfoil element 200 in FIG. 9, but show alternative designs of the airfoil element 200, that is, in particular of the thickness extension of the airfoil elements 200 over the length of the airfoil elements 200, wherein the thickness extension forms through both the extension of the pressure side contour and the extension of the suction side contour.

In FIG. 17, starting from the proximal end 204 towards the distal end 202, both edges, forming the edge of the airfoil element 200 in the vertical direction herein, have convex shapes until reaching the region in which the airfoil element 200 is at its thickest. Between this region and the distal end 202, both edges have convex shapes.

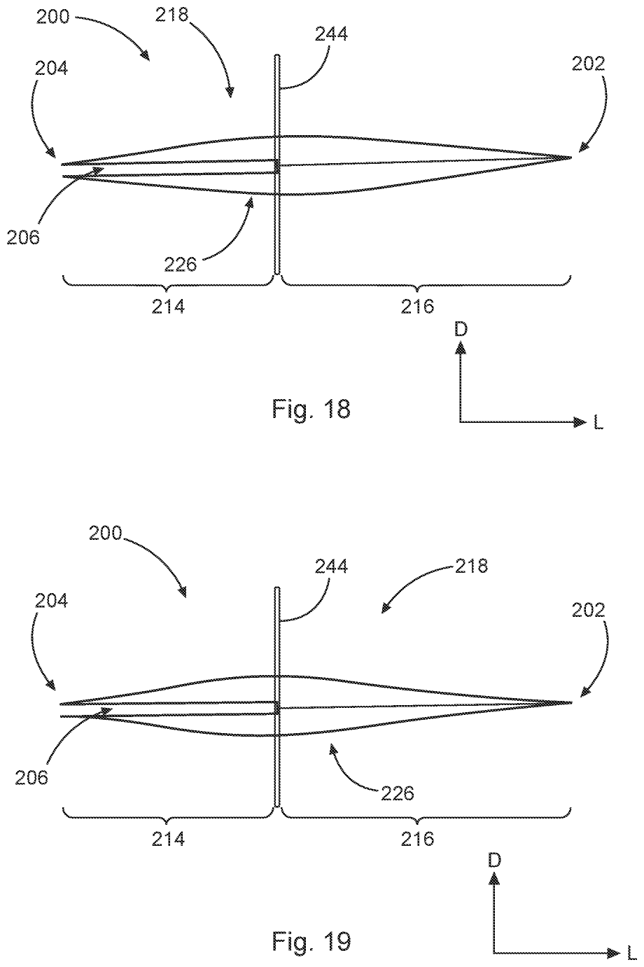

In FIG. 18 both edges have concave shapes until reaching the region in which the airfoil element 200 is at its thickest. Between this region and the distal end 202, both edges have convex shapes.

In FIG. 19 both edges have concave shapes until reaching the region in which the at least one airfoil element 200 is at its thickest. In the region in which the at least one airfoil element 200 is at its thickest, both edges have convex shapes. Between this region and the distal end 202, both edges have concave shapes.

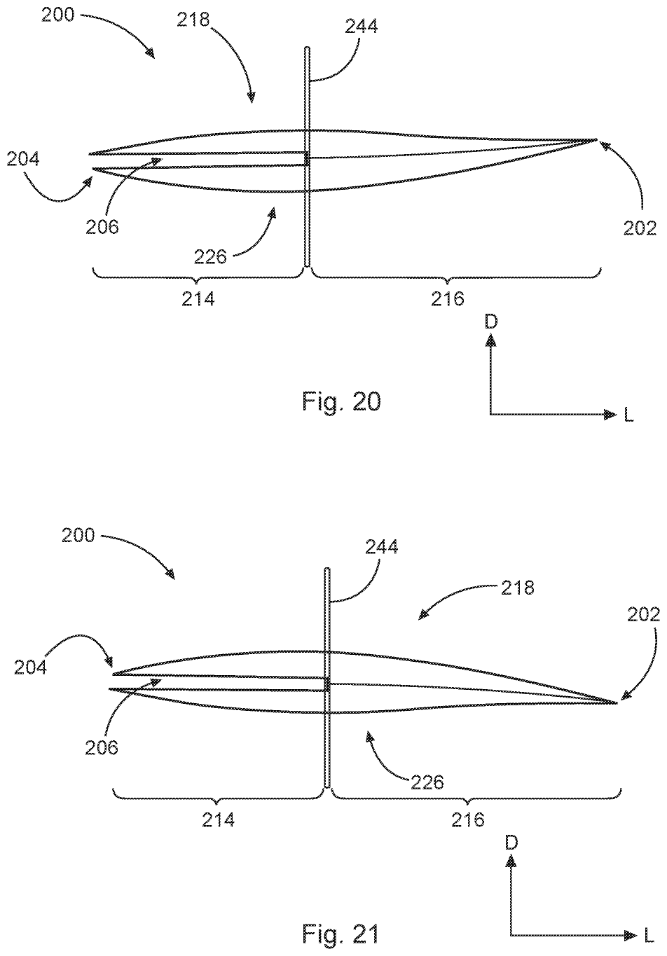

FIG. 20 shows a possible geometric form of the at least one airfoil element 200 in the direction of the length L and the thickness D of the at least one airfoil element 200. The mounting gap 206 extends from the proximal end 204 to the projecting plane 244. After the projecting plane 244, in the direction of the distal end 202, the projecting part of the at least one airfoil element 200 has a negative camber, wherein a negative camber means a camber in the direction of the suction side airfoil side 218.

In FIG. 21, in contrast to FIG. 20, the projecting part of the at least one airfoil element 200 has a positive camber, wherein a positive camber means a camber in the direction of the pressure side airfoil side 226.

In FIG. 22 the projecting part of the at least one airfoil element 200 has a combination of a positive and a negative camber. In other words, the projecting part of the at least one airfoil element 200 has portions disclosing a positive camber as well as portions disclosing a negative camber, after the projecting plane 244 in the direction of the distal end 202.

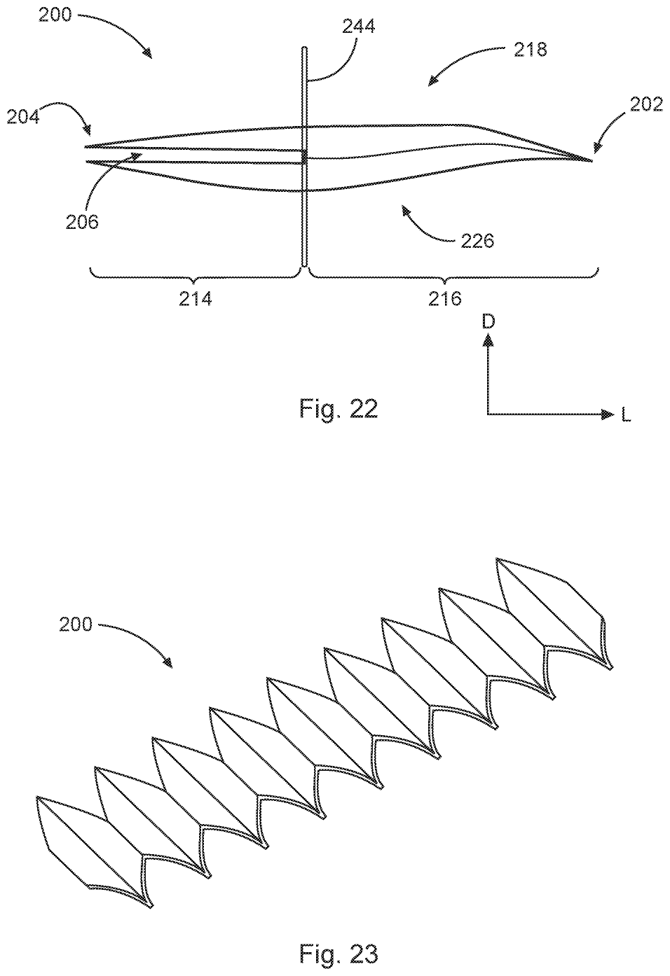

FIG. 23 shows a schematic, three-dimensional view of the airfoil element 200. The at least one airfoil element has a plurality of arrowhead shapes, wherein each arrowhead shape overlaps the directly adjacent arrowhead shape(s) and the respective overlapping portions are like vertically cut and then glued to these cutting positions. Here, the overlapping portions extend to about one third of the distance between the proximal end and the distal end of the respective overlapping arrowhead shapes. In the embodiment shown herein all arrowhead shapes of the at least one airfoil element 200 have the same length, which length is to be understood as the distance between the proximal end and the distal end of the respective arrowhead shapes. In the embodiment shown herein, the overlapping portions all have the same length as well.

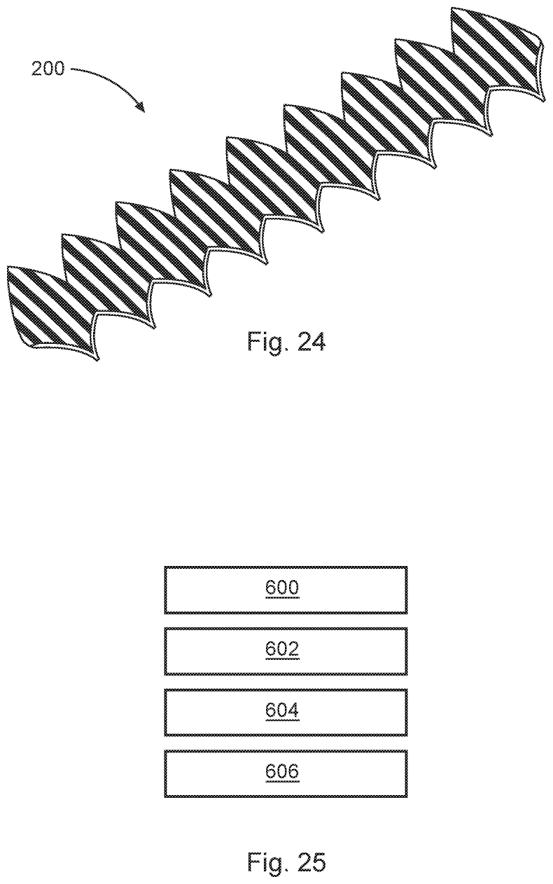

FIG. 24 shows a schematic, three-dimensional view of the airfoil element 200. The at least one airfoil element has a plurality of arrowhead shapes, wherein each arrowhead shape overlaps the directly adjacent arrowhead shape(s) and the respective overlapping portions are like vertically cut and then glued to these cutting positions. In the embodiment shown herein, all arrowhead shapes of the at least one airfoil element 200 have multiple grooves and multiple ridge lines, as can be seen in FIG. 5, for example. Accordingly, in FIG. 24, multiple airfoil elements 200 as shown in FIG. 5 are arranged adjacent to one another.

FIG. 25 shows a schematic method. In step 600 at least one airfoil element 200 is provided, having a cross-section with at least one local minimum of the airfoil element thickness. In step 602 the at least one airfoil element 200 is arranged at a trailing edge 114 of a rotor blade 108. In step 604 the at least one airfoil element 200 is arranged at the trailing edge 114 such that a portion of the trailing edge 114 is arranged inside the mounting gap 206. In step 606 the at least one airfoil element 200 is glued to a trailing edge region 116 adjoining the trailing edge 114.

Some embodiments improve previously used trailing edge serrations (TES) and combines them with the benefits of so-called finlets, which are small-sized fins to be attached to the trailing edges, oriented vertically with respect to the blade surface, for attenuating pressure shifts over the rotor's span. In this way, airfoil elements 200 different from previous TES were developed. Due to their appearance, the new airfoil elements 200 are also termed “squid TES” (Kalmar-TES) and combine the concepts of finlets and TES into one element.

The squid TES or airfoil elements 200 are three-dimensional elements. In a first variant, each individual tooth has a sharp ridge extending in the longitudinal direction, sloping down from the center line to the side and laterally transitioning into the blade surface in a tangentially constant way. For securely gluing the squid TES, the airfoil element is pushed up to the projecting plane 244.

In order to avoid flow separation due to dam-up effects at the leading edge of the airfoil element 200 during operation of the rotor blade 108, the surface slopes up in a small angle to the ridge here as well. This means that the front face of the forward-facing inflow edge is near zero. In a case where multiple squid TES are arranged over the rotor's span, as shown in FIG. 23 or 24, for example, a symmetrical pattern of ridges and valleys is formed. This structural arrangement of the airfoil elements 200 disrupts the turbulent structures in the boundary layer, in particular the components within the rotor's span. The disrupted structures may then flow out via the TES as smaller structures.

Moreover, it is expected that due to the three-dimensional structure of the squid TES, i.e., the airfoil elements 200, the directivity pattern of the dominant noise sources is changed in such a way that the emissions of the noise source become more diffuse and, ideally, less noise reaches the prescribed measuring position for noise level measurements of the wind turbine 100.

Up to now, a maximum value of the noise level caused by the dipole-like emission pattern of the trailing edge noise tends to occur at this measuring position. The width of the squid TES determines the particularly affected length scales. In addition, the length/width ratio of the TES may also be optimized.

When the airfoil element 200 is further modified, as shown in FIG. 24 and FIG. 7, by applying multiple grooves (multiple ridges and valleys) onto squid TES (see FIG. 3), a targeted adaptation of the three-dimensional structure to an even smaller “wavelength” is possible. The depth and width of the grooves and the angle with respect to the ridge may be varied and optimized in order to affect the desired length scales in the turbulent boundary layer in a particularly advantageous manner. When the TES airfoil elements 200, cf. FIG. 24, are arranged within the rotor's span, the length scale to be affected remains the same. Depending on the variant, large-scale or small-scale turbulence structures are more likely to be changed, which will also be reflected by the effect of the squid TES in various frequency bands. In this way, a targeted adaptation to the dominant frequency range of the trailing edge noise is possible.

Since the airfoil elements 200 are only pushed over and glued to the trailing edges, integration is made cheaper and perfectly suitable as a retrofit solution. In addition, there will be benefits regarding the lifetime of the element, as the airfoil elements 200 are glued to the airfoil from both sides, so they are protected from becoming detached. For even better gluing, the squid TES may also be composed of two half-shells, which are glued to the pressure and the suction side separately.

### REFERENCE SIGNS

100 wind turbine
102 tower
104 nacelle
106 rotor
108 rotor blades
110 spinner
112 leading edge
114 trailing edge
116 trailing edge region
118 suction side
120 pressure side
122 projecting direction
200 airfoil element
202 distal end
204 proximal end
206 mounting gap
208 ridge line
210 first airfoil surface
212 second airfoil surface
214 proximal portion
216 distal portion
218 suction side airfoil side
220 first airfoil surface
222 second airfoil surface
224 ridge line or ridge edge
226 pressure side airfoil side
228 groove
230 groove
232 groove
234 groove
236 groove
238 groove
240 groove
242 groove
244 projecting plane
246 first airfoil unit
248 second airfoil unit

European patent application no. 22214731.6, filed Dec. 19, 2022, to which this application claims priority, is hereby incorporated herein by reference in its entirety. Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. A rotor blade of a wind turbine, wherein the rotor blade has a leading edge, a trailing edge, a suction side and a pressure side, and extends in a longitudinal direction of a rotor blade between a root end and a tip end,
wherein a direct connection between the leading edge and the trailing edge is termed the chord line and the length thereof is termed the chord length,
wherein the rotor blade has at least one airfoil element, wherein the at least one airfoil element is arranged at the trailing edge with a proximal portion adjoining a trailing edge region and projects from the trailing edge with a distal portion having a projecting direction, which is oriented substantially parallel to the direction of the chord length,
wherein the at least one airfoil element has an airfoil element thickness in a direction perpendicular to the projecting direction,
wherein the at least one airfoil element has a pressure side airfoil side facing the pressure side and a suction side airfoil side facing the suction side,
wherein the at least one airfoil element has a cross-section substantially orthogonal to the projecting direction,
wherein the cross-section of the at least one airfoil element has at least one local minimum of the airfoil element thickness, wherein the airfoil element thickness in the cross-section on both sides of the local minimum has a larger value.

2. The rotor blade according to claim 1, wherein the at least one airfoil element has multiple cross-sections at different positions in a direction parallel to the projecting direction, wherein each of the multiple cross-sections has at least one respective local minimum of the airfoil element thickness on a common line, wherein the connection of all local minimums on a common line is termed a groove, and
wherein each of the multiple cross-sections has at least one respective local maximum of the airfoil element thickness on a common line, wherein the connection of all local maximums on a common line is termed a ridge line.

3. The rotor blade according to claim 2, wherein the at least one airfoil element has, for each groove:
an airfoil surface located on the rotor blade root side of the individual grooves and extending between the respective groove and the ridge line, which is located on the same airfoil side directly on the rotor blade root side of the individual groove, wherein the airfoil surface has an airfoil element thickness decreasing in the direction of the rotor blade tip side, and
an airfoil surface located on the rotor blade tip side of the individual grooves and extending between the respective groove and the ridge line, which is located on the same airfoil side directly on the rotor blade tip side of the individual groove, wherein the airfoil surface has an airfoil element thickness increasing in the direction of the rotor blade tip side,
wherein each airfoil surface is formed convex, concave or straight.

4. The rotor blade according to claim 2, wherein the at least one airfoil element has a first airfoil surface on the pressure side airfoil side and/or on the suction side airfoil side, starting from a rotor blade root side, wherein the first airfoil surface has an airfoil element thickness increasing in the direction of the rotor blade tip side, and wherein the first airfoil surface reaches its maximum airfoil element thickness along a first ridge line, which extends parallel to the chord line,
wherein each airfoil surface is formed convex, concave or straight.

5. The rotor blade according to claim 2, wherein the at least one airfoil element has a final airfoil surface on the pressure side airfoil side and/or on the suction side airfoil side, starting from a rotor blade root side, on the rotor blade tip side of the final ridge line, in the direction of the rotor blade tip side, wherein the final airfoil surface has an airfoil element thickness decreasing in the direction of the rotor blade tip side, and wherein the final airfoil surface reaches its minimum airfoil element thickness along the edge of the at least one airfoil element,
wherein each airfoil surface is formed convex, concave or straight.

6. The rotor blade according to claim 3, wherein each airfoil surface of the at least one airfoil element extends from a distal end towards a proximal end of the at least one airfoil element.

7. The rotor blade according to claim 3, wherein each airfoil surface of the at least one airfoil element adjoining a groove is formed substantially congruent with the second airfoil surface adjoining the same groove.

8. The rotor blade according to claim 2, wherein at least one ridge line of the at least one airfoil element has a sharp edge.

9. The rotor blade according to claim 2, wherein at least one groove of the at least one airfoil element has a sharp edge.

10. The rotor blade according to claim 2, wherein each ridge line and each groove of the pressure side airfoil side of the at least one airfoil element is arranged perpendicularly with respect to the projecting direction in each point, below a respective ridge line and a respective groove of the suction side airfoil side of the at least one airfoil element.

11. The rotor blade according to claim 1, wherein the pressure side airfoil side of the at least one airfoil element is a reflection of the suction side airfoil side with respect to the plane spanned by the trailing edge and the projecting direction.

12. The rotor blade according to claim 1, wherein the proximal portion and the distal portion of the at least one airfoil element are formed in the shape of arrowheads, and wherein the proximal end and the distal end each are formed substantially round or pointed; for example, the proximal end may be pointed and the distal end may be round.

13. The rotor blade according to claim 1, wherein the proximal portion and the distal portion of the at least one airfoil element are formed from multiple arrowhead shapes arranged parallel to one another, wherein each arrowhead shape overlaps the directly adjacent arrowhead shape(s), and wherein for each arrowhead shape the proximal end and the distal end each are formed substantially round or pointed.

14. The rotor blade according to claim 1, wherein a mounting gap is formed between the pressure side airfoil side and the suction side airfoil side in the proximal portion, wherein the trailing edge region is at least partially arranged inside the mounting gap.

15. The rotor blade according to claim 1, wherein the at least one airfoil element is formed as two parts, wherein a first part has the pressure side airfoil side and a second part has the suction side airfoil side, wherein the first part is attached to the pressure side and the second part is attached to the suction side, preferably by gluing, wherein preferably the portions of the first part and the second part projecting from the trailing edge are attached together, preferably glued.

16. The rotor blade according to claim 1, wherein an element thickness forms between the pressure side airfoil side and the suction side airfoil side of the at least one airfoil element, and the element thickness increases from the proximal end towards a maximum element thickness at an airfoil element position and the element thickness decreases from this airfoil element position towards the distal end.

17. The rotor blade according to claim 1, comprising two or more airfoil elements that are arranged adjacent to one another along the trailing edges and abut against one another.

18. A wind turbine having a rotor blade according to claim 1.

19. A wind farm having multiple wind turbines according to claim 18.

20. A method for optimizing a rotor blade, wherein the rotor blade has a leading edge, a trailing edge, a suction side and a pressure side, and extends in a longitudinal direction of a rotor blade between a root end and a tip end,
wherein a direct connection between the leading edge and the trailing edge is termed the chord line and the length thereof is termed the chord length, comprising:
assembling at least one airfoil element, wherein the at least one airfoil element is arranged at the trailing edge with a proximal portion adjoining a trailing edge region and projects from the trailing edge with a distal portion having a projecting direction, which is oriented substantially parallel to the direction of the chord length,
wherein the at least one airfoil element has an airfoil element thickness in a direction perpendicular to the projecting direction between a plane spanned by the trailing edge and the projecting direction and the surface of the at least one airfoil element,
wherein the at least one airfoil element has a pressure side airfoil side facing the pressure side and a suction side airfoil side facing the suction side,
wherein the at least one airfoil element has a cross-section substantially orthogonal to the projecting direction,
wherein the cross-section of the at least one airfoil element has at least one local minimum of the airfoil element thickness, wherein the airfoil element thickness in the cross-section on both sides of the local minimum has a larger value.
